(19) United States
(12) Patent Application Publication
(10) Pub. No.: US 2012/0292082 A1
(43) Pub. Date: Nov. 22, 2012

(54) ANISOTROPIC CONDUCTIVE FILM

(75) Inventors: Kouichi Miyauchi, Tochigi (JP); Shinichi Sato, Tochigi (JP); Yasunobu Yamada, Tochigi (JP)

(73) Assignee: SONY CHEMICAL & INFORMATION DEVICE CORPORATION, Tokyo (JP)

(21) Appl. No.: 13/575,192

(22) PCT Filed: Sep. 15, 2011
(86) PCT No.: PCT/JP2011/071074

§ 371 Date: Jul. 25, 2012

(30) Foreign Application Priority Data
Nov. 9, 2010 (JP) 2010-250517

(51) Int. Cl. B32B 37/14; C09J 7/02; B32B 7/12; H05K 1/02

(52) U.S. Cl. 174/250; 428/355 EN; 156/60

(57) ABSTRACT

In an anisotropic conductive film formed by laminating an insulating adhesive layer containing a polymerizable acrylic compound, a film-forming resin, and a polymerization initiator and a conductive particle-containing layer containing a polymerizable acrylic compound, a film-forming resin, a polymerization initiator, and conductive particles, the insulating adhesive layer and the conductive particle-containing layer each contain a thiol compound in order not to decrease the adhesion strength to an adherend and to improve connection reliability. Examples of the thiol compound may include pentaerythritol tetrakis(3-mercaptopropionate), tris-[(3-mercaptopropionyloxy)-ethyl]-isocyanurate, trimethylolpropane tris(3-mercaptopropionate), and dipentaerythritol hexakis(3-mercaptopropionate).

### TECHNICAL FIELD

The present invention relates to an anisotropic conductive film.

### BACKGROUND ART

In order to connect a liquid crystal panel with a tape carrier package (TCP) substrate or a chip-on film (COF) substrate through a thermosetting anisotropic conductive film or to connect a printed wiring board (PWB) with a TCP substrate or a COF substrate through a thermosetting anisotropic conductive film, it has been proposed that a binder resin composition used for an anisotropic conductive film is composed of a polymerizable acrylic compound capable of curing at relatively low temperatures for a short time, a film-forming resin, an organic peroxide as a polymerization initiator, and the like to shorten a thermocompression bonding time (Patent Literature 1).

However, when an anisotropic conductive film containing the polymerizable acrylic compound and the organic peroxide as described above is subjected to anisotropic conductive connection at relatively low temperatures for a short time, the adhesion strength of the anisotropic conductive film to an electronic part or a flexible substrate is not sufficient. Therefore, there is a problem of insufficient connection reliability.

A TCP substrate is lower in package density and cost compared to a COF substrate, and has differences shown in Table 1 from the COF substrate. The TCP substrate is produced by laminating Cu on a polyimide base through an adhesive, but the COF substrate is produced by laminating Cu on a polyimide base without an adhesive. Therefore, the TCP substrate particularly differs from the COF substrate in this respect. For example, in order to bond the COF substrate and a PWB through an anisotropic conductive film, the anisotropic conductive film comes in direct contact with the polyimide base as a substrate. Therefore, this is different from the case of bonding of the TCP substrate and a PWB through an anisotropic conductive film. This difference causes a problem in which the adhesion strength (peel strength) between the COF substrate and the anisotropic conductive film is smaller than that between the TCP substrate and the anisotropic conductive film. In fact, it is necessary to properly and separately use an anisotropic conductive film for a TCP substrate and an anisotropic conductive film for a COF substrate during packaging. Further, there is also a problem in which a single anisotropic conductive film cannot be used for both of a TCP substrate and a COF substrate.

TABLE 1

| | Component | | | Property | | |
|---|---|---|---|---|---|---|
| | Thickness of | Thickness of | Thickness | | Adhesion | Wiring |
| Substrate | Polyimide Base | Adhesive Layer | of Cu | Hardness | Surface | Height |
| TCP | 75 μm | 12 μm | 18 μm | Hard | Adhesive | High |
| | | | | | Layer | |
| COF | 38 μm | None | 8 μm | Soft | Polyimide | Low |

In order to solve these problems, use of two-layer structure in which a conductive particle-containing layer and an insulating adhesive layer are laminated as a structure of anisotropic conductive film, use of two kinds of organic peroxides having different one-minute half-life temperatures as a polymerization initiator mixed in respective layers, and use of an organic peroxide having a higher one-minute half-life temperature of the two types of organic peroxides which produces benzoic acid resulting from the decomposition thereof have been proposed (Patent Literature 2).

### CITATION LIST

### Patent Literature

[Patent Literature 1] Japanese Patent Application Laid-Open No. 2006-199825
[Patent Literature 2] Japanese Patent Application Laid-Open No. 2010-37539

### SUMMARY OF THE INVENTION

### Problems to be Solved by the Invention

The anisotropic conductive film having a two-layer structure proposed in Patent Literature 2 exhibits adhesion to be originally intended, but has a problem in which connection reliability, particularly connection reliability after aging is insufficient.

The present invention is intended to solve the problems in the above conventional technology. Accordingly, an object of the present invention is not to decrease adhesion strength to an adherend and to improve connection reliability in a two-layer type anisotropic conductive film in which on a conductive particle-containing layer containing a polymerizable acrylic compound capable of curing at relatively lower temperatures for a shorter time compared to a thermosetting epoxy resin and a film-forming resin, an insulating adhesive layer containing a polymerizable acrylic resin compound together with a film-forming resin is laminated.

### Means for Solving the Problems

The present inventors have found that the conductive particle-containing layer and the insulating adhesive layer which constitute an anisotropic conductive film each contain a thiol compound functioning as a radical chain transfer agent to attain the above object. The present invention has been completed.

Therefore, the present invention provides an anisotropic conductive film formed by laminating an insulating adhesive layer containing a polymerizable acrylic compound, a film-forming resin, and a polymerization initiator and a conductive particle-containing layer containing a polymerizable acrylic compound, a film-forming resin, a polymerization initiator, and conductive particles, wherein

the insulating adhesive layer and the conductive particle-containing layer each contain a thiol compound.

The present invention provides a connection structure produced by connecting a connection portion of a first wiring substrate and a connection portion of a second wiring substrate through the above-described anisotropic conductive film by anisotropic conductive connection.

Further, the present invention provides a method for producing a connection structure including: holding the above-described anisotropic conductive film between a connection portion of a first wiring substrate and a connection portion of a second wiring substrate; temporarily bonding the anisotropic conductive film to the connection portions at a first temperature at which an organic peroxide having a lower one-minute half-life temperature dose not decompose; and bonding the anisotropic conductive film to the connection portions by thermocompression bonding at a second temperature at which an organic peroxide having a higher one-minute half-life temperature decomposes.

### Advantageous Effects of the Invention

The anisotropic conductive film of the present invention has a layered structure of a conductive particle-containing layer and an insulating adhesive layer which each contain a polymerizable acrylic compound, a film-forming resin, and a polymerization initiator. Each of the layers contains a thiol compound. Since the thiol compound functions as a radical chain transfer agent, the amount of radicals produced at the early stage of polymerization at relatively low temperature is relatively small. Accordingly, the thiol compound has a function of capturing a radical and slowing polymerization. Therefore, when the anisotropic conductive film is subjected to a thermocompression bonding treatment, excess binder resin can be relatively easily extruded from a gap between the adherends before curing. Accordingly, while adhesion strength cannot be caused to decrease, connection reliability can be improved.

### EMBODIMENTS FOR CARRYING OUT THE INVENTION

The anisotropic conductive film of the present invention has a two-layer structure in which an insulating adhesive layer and a conductive particle-containing layer are laminated. The insulating adhesive layer and the conductive particle-containing layer each contain a polymerizable acrylic compound, a film-forming resin, and a polymerization initiator. In addition, the conductive particle-containing layer contains conductive particles. Further, the insulating adhesive layer and the conductive particle-containing layer each contain a thiol compound. Accordingly, while adhesion strength can be maintained or improved, connection reliability, particularly connection reliability after aging can be improved.

In the anisotropic conductive film of the present invention, the insulating adhesive layer and the conductive particle-containing layer each contain one or more kinds of thiol compounds. The thiol compounds contained in the layers may be the same or different. As such a thiol compound, thiol compounds known as a chain transfer agent can be used. The use of the thiol compound functioning as a chain transfer agent can suppress the viscosity increasing phenomenon due to free radicals produced during storage of an acrylic resin composition used in the formation of an anisotropic conductive film, that is, a composition for formation of an insulating adhesive layer and a composition for formation of a conductive particle-containing layer. Specifically, particularly preferable examples of such a thiol compound may include compounds selected from the group consisting of pentaerythritol tetrakis(3-mercaptopropionate), tris-[(3-mercaptopropionyloxy)-ethyl]-isocyanurate, trimethylolpropane tris(3-mercaptopropionate), and dipentaerythritol hexakis(3-mercaptopropionate).

When the amount of the thiol compounds in the insulating adhesive layer of the anisotropic conductive film is too small, the initial connection resistance tends to increase. When the amount is too large, the adhesion strength tends to decrease. Therefore, the amount is preferably 0.5 to 5% by mass, and more preferably 0.5 to 2% by mass. On the other hand, when the amount of the thiol compounds in the conductive particle-containing layer of the anisotropic conductive film is too small, the initial connection resistance tends to increase, and when the amount is too large, the connection reliability tends to decrease. Therefore, the amount is preferably 0.3 to 4% by mass, and more preferably 0.5 to 2% by mass.

It is preferable that the amount of thiol compounds in the insulating adhesive layer should be equal to or more than that in the conductive particle-containing layer. Thus, an anisotropic conductive film exhibiting high adhesion strength and good connection reliability can be obtained.

Further, since the anisotropic conductive film has a layered structure of an insulating adhesive layer and a conductive particle-containing layer as described above, the anisotropic conductive film can be commonly used for a TCP substrate and a COF substrate. The reason is not obvious, but it is assumed as follows.

The insulating adhesive layer usually exhibits a glass transition temperature lower than that of the conductive particle-containing layer, and therefore is easily eliminated when the COF substrate or the TCP substrate is pressed against the anisotropic conductive film, and tends to widely exist between adjacent electrodes in a surface direction during bonding. The insulating adhesive layer is cured by radical polymerization at low temperatures during bonding. Further, the insulating adhesive layer is cured by radical polymerization at higher temperature, and the same time benzoic acid is produced. Therefore, the insulating adhesive layer is strongly bonded to a surface (metal electrode surface, polyimide surface, and conductive particle-containing layer surface) in contact with the COF substrate or the TCP substrate due to the produced benzoic acid, and is cured. The conductive particle-containing layer has a glass transition temperature higher than that of the insulating adhesive layer, and therefore the conductive particles are likely to exist between electrodes opposite to each other when the COF substrate or the TCP substrate is pressed against the anisotropic conductive film. Like the insulating adhesive layer, the conductive particle-containing layer is cured by radical polymerization at low temperatures. Further, the conductive particle-containing layer is cured by radical polymerization at higher temperatures, and the same time benzoic acid is produced. Therefore, the conductive particle-containing layer is strongly bonded to a surface of a PWB in contact with the COF substrate or the TCP substrate and is cured. Thus, the insulating adhesive layer exhibits stress relaxation and strong adhesive property to the COF substrate or the TCP substrate, and the conductive particle-containing layer exhibits good reliability of connection of the COF substrate or the TCP substrate with the PWB due to strong cohesive force thereof.

As the polymerization initiator constituting the anisotropic conductive film of the present invention, a radical polymerization initiator can be used. Examples thereof may include known organic peroxides and azo compounds, and organic peroxides can be more preferably used.

In particular, it is preferable that the conductive particle-containing layer of the anisotropic conductive film of the present invention contain two kinds of organic peroxides having different decomposition temperatures as a polymerization initiator. In this case, of the two kinds of organic peroxides, one organic peroxide which has a higher one-minute half-life temperature and produces benzoic acid or a derivative thereof by decomposition can be preferably used. Examples of the derivative of benzoic acid may include methyl benzoate, ethyl benzoate, t-butyl benzoate, and the like. A combination of the two kinds of organic peroxides may be the same or different in the insulating adhesive layer and the conductive particle-containing layer.

Like the conductive particle-containing layer, the insulating adhesive layer of the anisotropic conductive film of the present invention may contain two kinds of organic peroxides as a polymerization initiator. However, it is preferable that the insulating adhesive layer should contain only a high-temperature decomposition peroxide in terms of fluidity.

When two types of organic peroxides having different one-minute half-life temperatures are used as a polymerization initiator for a polymerizable acrylic compound, and one organic peroxide which has a higher one-minute half-life temperature (hereinafter sometimes referred to as a high-temperature decomposition peroxide) and decomposes to produce benzoic acid or a derivative thereof is used of the two kinds of organic peroxides, the effects described below can be obtained. When short-time thermocompression bonding is performed at a relatively higher temperature at which the decomposition of the high-temperature decomposition peroxide is promoted, the heating temperature increases, and the other organic peroxide having a relatively lower one-minute half-life temperature (hereinbelow sometimes referred to as a low-temperature decomposition peroxide) is caused to start decomposing at relatively lower temperatures at which thermal stress is not required to be taken into account. The presence of the low-temperature decomposition peroxide allows the polymerizable acrylic compound to cure sufficiently by polymerization. Subsequently, the high-temperature decomposition peroxide is caused to decompose, and the polymerization and curing of the polymerizable acrylic compound is finally completed. At this time, benzoic acid is produced. Part of the produced benzoic acid is present at or near an interface between the cured anisotropic conductive film and the connecting object, and therefore the adhesion strength can be improved.

In the anisotropic conductive film of the present invention, if the one-minute half-life temperature of the low-temperature decomposition peroxide of the two kinds of organic peroxides contained as the polymerization initiator is too low, the storage stability thereof before curing tends to lower. When it is too high, the degree of curing of the anisotropic conductive film tends to be insufficient. Therefore, the one-minute half-life temperature is preferably 80° C. or higher and lower than 120° C., and more preferably 90° C. or higher and lower than 120° C. On the other hand, a high-temperature decomposition peroxide having a lower one-minute half-life temperature is not commercially available. When the one-minute half-life temperature of the high-temperature decomposition peroxide is too high, benzoic acid or a derivative thereof tends not to be produced at the intended thermocompression bonding temperature. Therefore, the one-minute half-life temperature is preferably 120° C. or higher and 150° C. or lower.

When the difference in one-minute half-life temperature between the low-temperature decomposition peroxide and the high-temperature decomposition peroxide is too small, the low-temperature decomposition peroxide and the high-temperature decomposition peroxide react with the polymerizable acrylic compounds, resulting in decrease in the amount of benzoic acid contributing to the improvement of the adhesion strength. When the difference is too large, the curing reactivity of the anisotropic conductive film at low temperatures tends to decrease. Therefore, the difference in one-minute half-life temperature between the low-temperature decomposition peroxide and the high-temperature decomposition peroxide is preferably 10° C. or higher and 30° C. or lower.

When the mass ratio of the low-temperature decomposition peroxide to the high-temperature decomposition peroxide is too small, the curing reactivity of the anisotropic conductive film at low temperatures tends to decrease. On the other hand, when it is too large, the adhesion strength tends to decrease. Therefore, the mass ratio is preferably 10:1 to 1:5.

Specific examples of the low-temperature decomposition peroxide which can be used in the present invention may include diisobutyryl peroxide (one-minute half-life temperature: 85.1° C.), 1,1,3,3-tetramethylbutyl peroxy-2-ethylhexanoate (one-minute half-life temperature: 124.3° C.), dilauroyl peroxide (one-minute half-life temperature: 116.4° C.), di(3,5,5,-trimethylhexanoyl) peroxide (one-minute half-life temperature: 112.6° C.), t-butyl peroxypivalate (one-minute half-life temperature: 110.3° C.), t-hexyl peroxypivalate (one-minute half-life temperature: 109.1° C.), t-butyl peroxyneoheptanoate (one-minute half-life temperature: 104.6° C.), t-butyl peroxyneodecanoate (one-minute half-life temperature: 103.5° C.), t-hexyl peroxyneodecanoate (one-minute half-life temperature: 100.9° C.), di(2-ethylhexyl) peroxydicarbonate (one-minute half-life temperature: 90.6° C.), di(4-t-butylcyclohexyl) peroxydicarbonate (one-minute half-life temperature: 92.1° C.), 1,1,3,3-tetramethylbutyl peroxyneodecanoate (one-minute half-life temperature: 92.1° C.), di-sec-butyl peroxydicarbonate (one-minute half-life temperature: 85.1° C.), di-n-propyl peroxydicarbonate (one-minute half-life temperature: 85.1° C.), cumyl peroxyneodecanoate (one-minute half-life temperature: 85.1° C.), and the like. Two kinds thereof may be used in combination.

Specific examples of the high-temperature decomposition peroxide may include di(4-methylbenzoyl) peroxide (one-minute half-life temperature: 128.2° C.) di(3-methylbenzoyl) peroxide (one-minute half-life temperature: 131.1° C.), dibenzoyl peroxide (one-minute half-life temperature: 130.0° C.), t-hexyl peroxybenzoate (one-minute half-life temperature: 160.3° C.), t-butyl peroxybenzoate (one-minute half-life temperature: 166.8° C.), and the like. Two kinds thereof may be used in combination. The use of these high-temperature decomposition peroxides having a phenyl ring can improve the cohesive force of the anisotropic conductive film, and therefore the adhesion strength can be further improved.

In a combination of the low-temperature decomposition peroxide and the high-temperature decomposition peroxide, it is preferable that the former be dilauroyl peroxide and the later be dibenzoyl peroxide in terms of storage stability and adhesion strength.

In the anisotropic conductive film of the present invention, when the amount used of the polymerization initiator including the two different kinds of organic peroxides in the insulating adhesive layer or the conductive particle-containing layer is too small, the reactivity tends to be lost. When it is too large, the cohesive force of the anisotropic conductive film tends to decrease. Therefore, the amount used of the polymerization initiator is preferably 1 to 10 parts by mass based on 100 parts by mass of the polymerizable acrylic compound, and more preferably 3 to 7 parts by mass.

The polymerizable acrylic compound contained in each of the insulating adhesive layer and the conductive particle-containing layer of the anisotropic conductive film of the present invention is a compound having one or more acryloyl groups or methacryloyl groups (hereinafter referred to as (meth)acryloyl groups), preferably two or more (meth)acryloyl groups for improvement of conduction reliability, and particularly two (meth)acryloyl groups. Further, the polymerizable acrylic compounds in the insulating adhesive layer and the conductive particle-containing layer may be the same or different compounds.

Specific examples of the polymerizable acrylic compound may include polyethylene glycol diacrylate, phosphate ester acrylate, 2-hydroxyethyl acrylate, 2-hydroxypropyl acrylate, 4-hydroxybutyl acrylate, isobutyl acrylate, t-butyl acrylate, isooctyl acrylate, bisphenoxyethanolfluorene diacrylate, 2-acryloyloxyethyl succinate, lauryl acrylate, stearyl acrylate, isobornyl acrylate, tricyclodecane dimethanol dimethacrylate, cyclohexyl acrylate, tris(2-hydroxyethyl)isocyanurate triacrylate, tetrahydrofurfuryl acrylate, o-phthalic acid diglycidyl ether acrylate, ethoxylated bisphenol A dimethacrylate, bisphenol A type epoxy acrylate, urethane acrylate, epoxy acrylate, and (meth)acrylates corresponding thereto.

In terms of high adhesion strength and conduction reliability, 5 to 40 parts by mass of bifunctional acrylate, 10 to 40 parts by mass of urethane acrylate, and 0.5 to 5 parts by mass of phosphate ester acrylate are preferably used in combination as the polymerizable acrylic compound. The bifunctional acrylate is added to improve the cohesive force of the cured product and improve the conduction reliability. The urethane acrylate is added to improve the adhesion to polyimide, and the phosphate ester acrylate is added to improve the adhesion to metal.

When the amount used of each polymerizable acrylic compound in the insulating adhesive layer and the conductive particle-containing layer is too small, the conductive reliability tends to decrease. When it is too large, the adhesion strength tends to decrease. Therefore, the amount used of the polymerizable acrylic compound is preferably 20 to 70% by mass of the solid amount of the resin (total of the polymerizable acrylic compound and the film-forming resin), and more preferably 30 to 60% by mass.

As the film-forming resin used in each of the insulating adhesive layer and the conductive particle-containing layer of the anisotropic conductive film of the present invention, thermosetting elastomers such as an epoxy resin, a polyester resin, a polyurethane resin, a phenoxy resin, polyamide, and EVA can be used. Among these, because of heat resistance and adhesion, a polyester resin, a polyurethane resin, or a phenoxy resin can be used. In particular, a phenoxy resin can be used. Examples thereof may include a bisphenol-A type epoxy resin and a phenoxy resin having a fluorene skeleton. The phenoxy resin having a fluorene skeleton is characterized in that the glass transition point of the cured product is caused to increase. Therefore, it is preferable that the phenoxy resin be mixed only in the conductive particle-containing layer not in the insulating adhesive layer. In this case, the amount of the phenoxy resin having a fluorene skeleton in the film-forming resin is preferably 3 to 30% by mass, and more preferably 5 to 25% by mass.

When an epoxy resin is used as the film-forming resin, an epoxy resin having an epoxy equivalent of 15000 or more is preferable to suppress a reaction of the epoxy resin and a thiol compound.

When the amount used of the film-forming resin in each of the insulating adhesive layer and the conductive particle-containing layer of the anisotropic conductive film of the present invention is too small, a film is not formed. When it is too large, the exclusion property of the resin for attaining electric connection tends to decrease. Therefore, the amount used of the film-forming resin is preferably 30 to 80% by mass of the solid amount of the resin (total of the polymerizable acrylic compound and the film-forming resin), and more preferably 40 to 70% by mass.

As conductive particles used in the conductive particle-containing layer of the anisotropic conductive film of the present invention, conductive particles used in the conventional anisotropic conductive films can be used. For example, metal particles such as gold particles, silver particles, and nickel particles, and metal-coated resin particles formed by coating the surface of particles of resins such as a benzoguanamine resin and a styrene resin with metals such as gold, nickel, and zinc can be used. The average particle diameter of such conductive particles is usually 1 to 10 μm, and more preferably 2 to 6 μm.

When the amount used of the conductive particles in the conductive particle-containing layer of the anisotropic conductive film is too small, the probability of conduction failure increases. When it is too large, the probability of short circuit increases. Therefore, the amount used of the conductive particles is preferably 0.1 to 20 parts by mass based on 100 parts by mass of the solid amount of the resin, and more preferably 0.2 to 10 parts by mass.

If necessary, the insulating adhesive layer and the conductive particle-containing layer of the anisotropic conductive film of the present invention may each contain diluting monomers such as various acrylic monomers, a filler, a softening agent, a colorant, a flame retardant, a thixotropic agent, a coupling agent, and the like.

When the thickness of the insulating adhesive layer of the anisotropic conductive film of the present invention is too small, the adhesion strength tends to decrease, and when it is too large, the conduction reliability tends to decrease. Therefore, the thickness of the insulating adhesive layer is preferably 10 to 25 μm, and more preferably 16 to 21 μm. When the thickness of the conductive particle-containing layer is too small, the conduction reliability tends to decrease, and when it is too large, the adhesion strength tends to decrease. Therefore, the thickness of the conductive particle-containing layer is preferably 10 to 25 μm, and more preferably 15 to 20 μm. When the thickness of the anisotropic conductive film formed of the insulating adhesive layer and the conductive particle-containing layer is too small, filling is not enough, and accordingly, the adhesion strength tends to decrease. When it is too large, pressing is not enough, and the probability of conduction failure increases. Therefore, the thickness of the anisotropic conductive film is preferably 25 to 50 μm, and more preferably 30 to 45 μm.

The glass transition temperature of the cured product of each of the insulating adhesive layer and the conductive particle-containing layer of the anisotropic conductive film of the present invention is an important factor of using the anisotropic conductive film as an under filling agent. For this reason, the glass transition temperature of the cured product of the insulating adhesive layer is preferably 50 to 100° C. and more preferably 65 to 100° C. On the other hand, the glass transition temperature of the cured product of the conductive particle-containing layer is preferably 80 to 130° C. and more preferably 85 to 130° C. In this case, it is preferable that the glass transition temperature of the cured product of the conductive particle-containing layer should be set to be higher than that of the cured product of the insulating adhesive layer. This allows the insulating adhesive layer to be fluidized as rapidly as possible and to be eliminated from a gap between electrodes opposite to each other during a connection operation. Specifically, the temperature needs to be higher by preferably 0 to 25° C., and more preferably 10 to 20° C.

The anisotropic conductive film of the present invention can be produced in accordance with the same method as that used for the conventional anisotropic conductive films. For example, the polymerizable acrylic compound, the film-forming resin, the polymerization initiator, and if necessary, other additives are uniformly mixed in a solvent such as methyl ethyl ketone to obtain a composition for formation of an insulating adhesive layer. The composition for formation of an insulating adhesive layer is applied to the surface of a release sheet subjected to release treatment and dried to form an insulating adhesive layer. The polymerizable acrylic compound, the film-forming resin, the conductive particles, the polymerization initiator, and if necessary, other additives are uniformly mixed in a solvent such as methyl ethyl ketone to obtain a composition for formation of a conductive particle-containing layer. The composition for formation of a conductive particle-containing layer is applied to surface of the insulating adhesive layer and dried to form a conductive particle-containing layer. In this manner, the anisotropic conductive film of the present invention can be obtained.

The anisotropic conductive film of the present invention can be preferably used for a connection structure in which a connection portion of a first wiring substrate and a connection portion of a second wiring substrate are connected to each other by anisotropic conductive connection. The first and second wiring substrates are not particularly limited, and examples thereof may include glass substrates of liquid crystal panels and flexible wiring substrates. Further, no particular limitation is imposed on the connection portions of the respective substrates, and connection portions to which the conventional anisotropic conductive film is applied may be used.

As described above, the anisotropic conductive film of the present invention can be used in various cases. In particular, when the first wiring substrate is a two- or three-layer flexible printed circuit substrate, a COF substrate, or a TCP substrate, and the second wiring substrate is a PWB, the anisotropic conductive film can be preferably used. This is because the anisotropic conductive film can be used for both of the TCP substrate and the COF substrate. In this case, the film-forming resin in the conductive particle-containing layer preferably contains a phenoxy resin having a fluorene skeleton. Thus, the glass transition temperature of the cured product of the conductive particle-containing layer can rise higher than that of the insulating adhesive layer, whereby the connection reliability of the anisotropic conductive film can be improved.

In the above-described connection structure, the insulating adhesive layer in the anisotropic conductive film is preferably disposed on the side of the first wiring substrate. This can improve the adhesion strength to a polyimide surface on which an adhesive layer is not formed.

The connection structure can be produced by holding the anisotropic conductive film of the present invention between the connection portions of the first and second wiring substrates so that the insulating adhesive layer is usually disposed on the first wiring substrate side, temporarily adhering the anisotropic conductive film to the connection portions at a first temperature at which an organic peroxide having a lower one-minute half-life temperature dose not decompose, and bonding the anisotropic conductive film to the connection portions by thermocompression bonding at a second temperature at which an organic peroxide having a higher one-minute half-life temperature decomposes. Further, the organic peroxide having the lower one-minute half-life temperature, the organic peroxide having the higher one-minute half-life temperature, preferable one-minute half-life temperatures thereof, and a preferable temperature difference therebetween have already been described. It is preferable that the first temperature should be lower than the one-minute half-life temperature of the organic peroxide having the lower one-minute half-life temperature by −20° C. or lower. It is preferable that the second temperature should be higher than the one-minute half-life temperature of the organic peroxide having the lower one-minute half-life temperature by −20° C. or higher.

### EXAMPLES

Hereinafter, the present invention will be more specifically described by Examples.

### Examples 1 to 12 and Comparative Examples 1 to 6

Materials in each of mixing compositions shown in Table 2 were uniformly mixed by a common method to prepare a composition for formation of a conductive particle-containing layer and a composition for formation of an insulating adhesive layer. The composition for formation of an insulating adhesive layer was then applied onto a release-treated polyester film with a bar coater so as to have a dry thickness of 18 μm, and dried with hot air at 70° C. for 5 minutes to form an insulating adhesive layer. Then the composition for formation of a conductive particle-containing layer was applied onto the insulating adhesive layer with a bar coater so as to have a dry thickness of 17 μm, and dried with hot air at 70° C. for 5 minutes to form a conductive particle-containing layer. In this manner, an anisotropic conductive film was obtained.

TABLE 2

| | Composition for | Composition for |
|---|---|---|
| | Formation of | Formation of |
| | Conductive Particle- | Insulating |
| | Containing Layer | Adhesive Layer |
| Component Name | (Part By Mass) | (Part By Mass) |
| Bisphenol A Type Epoxy | 30 | 40 |
| Phenoxy Resin (YP-50, Tohto | | |
| Kasei Co., Ltd.) | | |
| Bifunctional Acrylic Monomer | 30 | 30 |
| (A-200, Shin Nakamura | | |
| Chemical Co., Ltd.) | | |
| Urethane Acrylate (U-2PPA, | 20 | 20 |
| Shin Nakamura Chemical Co., | | |
| Ltd.) | | |
| Phosphate Ester Acrylate (PM- | 5 | 5 |
| 2, Nippon Kayaku Co., Ltd.) | | |
| Ni Particle (Particle Diameter | 2 | 0 |
| 3 μm) | | |
| Dilauroyl Peroxide (Low- | 3 | 0 |
| Temperature Decomposition) | | |
| Dibenzoyl Peroxide (High- | 3 | 3 |
| Temperature Decomposition) | | |
| Thiol Compound (See Table 3) | (See Table 3) | (See Table 3) |
| PEMP, TEMPIC, TMMP or | | |
| DPMP | | |

<Table 2 Note (thiol compound)>
PEMP: pentaerythritol tetrakis(3-mercaptopropionate), SC Organic Chemical Co., Ltd.
TEMPIC: tris-[(3-mercaptopropionyloxy)-ethyl]-isocyanurate, SC Organic Chemical Co., Ltd.
TMMP: trimethylolpropane tris(3-mercaptopropionate), SC Organic Chemical Co., Ltd.
DPMP: dipentaerythritol hexakis(3-mercaptopropionate), SC Organic Chemical Co., Ltd.
EHMP: 2-ethylhexyl-3-mercaptopropionate, SC Organic Chemical Co., Ltd.
EGMP-4: tetraethylene glycol bis(3-mercaptopropionate), SC Organic Chemical Co., Ltd.

In order to evaluate the adhesion strength and the connection reliability (at the early stage and after aging) of the obtained anisotropic conductive film, a connection structure was produced using the anisotropic conductive film as described below.

### <Production of Connection Structure>

The anisotropic conductive film was disposed on a printed wiring board (PWB) in which a wiring having a pitch of 200 μm was formed on copper foil having a thickness of 35 μm on the surface of a glass epoxy substrate so that the side of the conductive particle-containing layer is on the PWB side. The anisotropic conductive film was subjected to thermocompression bonding under conditions of 80° C., 1 MPa, and 2 seconds. Then, the release PET was peeled off, and the anisotropic conductive film was temporarily bonded to the surface of the PWB. A copper wiring portion of the COF substrate (a wiring substrate in which a copper wiring having a pitch of 200 μm and a thickness of 8 μm was formed on a polyimide film having a thickness of 38 μm) was mounted on the anisotropic conductive film. The copper wiring portion was bonded to the anisotropic conductive film by compression under conditions of 130° C., 3 MPa, and 3 seconds, or 190° C., 3 MPa, and 5 seconds to obtain a connection structure for evaluation.

### <Adhesion Strength Test>

A 90° peel test (JIS K6854-1) at a peel rate of 50 mm/minute was performed with a peel testing machine (A&D Company, Limited), the peel strength of the COF substrate against the PWB of the obtained connection structure was measured as the adhesion strength and evaluated by the following criteria. In practice, it is desirable that the adhesion strength should be AA or A rank.

### Rank Criterion

AA: 10 [N/5 cm] or more

A: 7 [N/5 cm] or more and less than 10 [N/5 cm]

B: 5 [N/5 cm] or more and less than 7 [N/5 cm]

C: less than 5 [N/5 cm]

### <Connection Reliability Test>

The conduction resistance (Ω: maximum value) at the early stage of the obtained connection structure and the after-aging conduction resistance (Ω: maximum value) after holding the connection structure in a thermostatic bath at 85° C. and 85% RH for 500 hours were measured with a multimeter (Part number: 34401A, Aglient) according to the four-terminal method (JIS K 7194), and evaluated by the following criteria. In practice, it is desirable that both of the conduction resistances at the early stage and after aging should be at least B rank.

### Rank Criterion

AA: 0.7Ω or less

A: more than 0.7Ω and 1.5Ω or less

B: more than 1.5Ω and 2Ω or less

C: more than 2Ω

TABLE 3

| | Example | | | | | | | | |
|---|---|---|---|---|---|---|---|---|---|
| | 1 | 2 | 3 | 4 | 5 | 6 | 7 | 8 | 9 |
| Amount of Thiol | 0.5 | 2 | 4 | 2 | 2 | 2 | 2 | 2 | 2 |
| Compound in Insulating | | | | | | | | | |
| Adhesive Layer (wt %) | | | | | | | | | |
| Amount of Thiol | 0.5 | 2 | 1 | 2 | 2 | 2 | 2 | 2 | 2 |
| Compound in Conductive | | | | | | | | | |
| Particle-Containing | | | | | | | | | |
| Layer (wt %) | | | | | | | | | |
| Thiol Compound in | PEMP | PEMP | PEMP | TEMPIC | TMMP | DPMP | PEMP | PEMP | PEMP |
| Insulating Adhesive Layers | | | | | | | | | |
| Thiol Compound in | PEMP | PEMP | PEMP | TEMPIC | TMMP | DPMP | TEMPIC | TMMP | DPMP |
| Conductive Particle- | | | | | | | | | |
| Containing Layer | | | | | | | | | |
| Adhesion Strength | A | AA | AA | AA | AA | A | AA | AA | A |
| Connection Reliability | A | AA | AA | AA | AA | B | AA | AA | B |
| at Early Stage | | | | | | | | | |
| Connection Reliability | B | AA | AA | AA | AA | B | AA | AA | B |
| After Aging | | | | | | | | | |

| | Example | | | Comparative Example | | | | | |
|---|---|---|---|---|---|---|---|---|---|
| | 10 | 11 | 12 | 1 | 2 | 3 | 4 | 5 | 6 |
| Amount of Thiol | 2 | 2 | 2 | — | 0.5 | — | — | — | — |
| Compound in Insulating | | | | | | | | | |
| Adhesive Layer (wt %) | | | | | | | | | |
| Amount of Thiol | 2 | 2 | 2 | 0.5 | — | — | 4 | 4 | 4 |
| Compound in Conductive | | | | | | | | | |
| Particle-Containing | | | | | | | | | |
| Layer (wt %) | | | | | | | | | |
| Thiol Compound in | EHMP | EGMP- | DPMP | — | DEMP | — | — | — | — |
| Insulating Adhesive Layers | | 4 | | | | | | | |
| Thiol Compound in | PEMP | PEMP | PEMP | DEMP | — | — | EHMP | EGMP- | DPMP |
| Conductive Particle- | | | | | | | | 4 | |
| Containing Layer | | | | | | | | | |
| Adhesion Strength | A | A | A | A | A | A | C | C | C |
| Connection Reliability | A | A | A | B | B | C | D | D | D |
| at Early Stage | | | | | | | | | |
| Connection Reliability | A | A | A | C | C | C | D | D | D |
| After Aging | | | | | | | | | |

As seen from Table 3, the anisotropic conductive films of Examples 1 to 12 in which a thiol compound is contained in both of the conductive particle-containing layer and the insulating adhesive layer exhibit practically preferable results for the adhesion strength and the connection reliability. In contrast, the anisotropic conductive films of Comparative Examples 1 to 6 in which a thiol compound is not contained in at least one of the conductive particle-containing layer and the insulating adhesive layer have a problem of connection reliability.

The connection reliability after aging of the anisotropic conductive film of Example 1 was ranked as “B.” This is considered because the amount of the thiol compound in each of the conductive particle-containing layer and the insulating adhesive layer is relatively small.

The connection reliabilities at the early stage and after aging of the anisotropic conductive films of Examples 6 and 9 were ranked as “B.” This is considered because DPMP has been used in the conductive particle-containing layer as the thiol compound.

The adhesion strengths of the anisotropic conductive films of Comparative Examples 4 to 6 were ranked as “C,” and the connection reliabilities at the early stage and after aging thereof were ranked as “D.” This is considered because the thiol compound has been added to only the conductive particle-containing layer and the added amount thereof is relatively large compared to that in Examples.

### INDUSTRIAL APPLICABILITY

The anisotropic conductive film of the present invention has a two-layer structure formed by laminating an insulating adhesive layer containing a polymerizable acrylic compound, a film-forming resin, and a polymerization initiator on a conductive particle-containing layer containing a polymerizable acrylic compound, a film-forming resin, a polymerization initiator, and conductive particles, in which both the layers each contain a thiol compound. Therefore, while the adhesion strength cannot be caused to decrease, the connection reliability can be improved. Accordingly, the anisotropic conductive film is useful for highly reliable anisotropic connection of precision electronic components.

1. An anisotropic conductive film formed by laminating an insulating adhesive layer containing a polymerizable acrylic compound, a film-forming resin, and a polymerization initiator and a conductive particle-containing layer containing a polymerizable acrylic compound, a film-forming resin, a polymerization initiator, and conductive particles, wherein
the insulating adhesive layer and the conductive particle-containing layer each contain a thiol compound.

2. The anisotropic conductive film according to claim 1, wherein amounts of the thiol compounds in the insulating adhesive layer and the conductive particle-containing layer are 0.5 to 5% by mass and 0.3 to 4% by mass, respectively.

3. The anisotropic conductive film according to claim 1, wherein the amount of the thiol compound in the insulating adhesive layer is equal to or more than the amount of the thiol compound in the conductive particle-containing layer.

4. The anisotropic conductive film according to claim 1, wherein the thiol compounds in the insulating adhesive layer and the conductive particle-containing layer are separately a compound selected from the group consisting of pentaerythritol tetrakis(3-mercaptopropionate), tris-[(3-mercaptopropionyloxy)-ethyl]-isocyanurate, trimethylolpropane tris(3-mercaptopropionate), and dipentaerythritol hexakis(3-mercaptopropionate).

5. The anisotropic conductive film according to claim 1, wherein the polymerization initiator is an organic peroxide.

6. The anisotropic conductive film according to claim 5, wherein: the polymerization initiator contained in the conductive particle-containing layer includes two types of organic peroxides having different one-minute half-life temperatures; one organic peroxide which has a higher one-minute half-life temperature among the two types of organic peroxides decomposes to produce benzoic acid or a derivative thereof, and the polymerization initiator contained in insulating adhesive layer is the organic peroxide which has a higher one-minute half-life temperature.

7. The anisotropic conductive film according to claim 6, wherein an organic peroxide which has a lower one-minute half-life temperature among the two types of organic peroxides is dilauroyl peroxide, and the organic peroxide which has a higher one-minute half-life temperature is dibenzoyl peroxide.

8. The anisotropic conductive film according to claim 1, wherein the polymerizable acrylic compound contains a phosphate ester acrylate, and the film-forming resin contains a polyester resin, a polyurethane resin, or a phenoxy resin.

9. A connection structure produced by connecting a connection portion of a first wiring substrate and a connection portion of a second wiring substrate through the anisotropic conductive film according to claim 7 by anisotropic conductive connection.

10. The connection structure according to claim 9, wherein the first wiring substrate is a chip-on film substrate or a tape carrier package substrate, the second wiring substrate is a printed wiring board, and the insulating adhesive layer of the anisotropic conductive film is disposed on a side of the first wiring substrate.

11. A method for producing a connection structure, comprising: holding the anisotropic conductive film according to claim 1 between a connection portion of a first wiring substrate and a connection portion of a second wiring substrate; temporarily bonding the anisotropic conductive film to the connection portions at a first temperature at which an organic peroxide having a lower one-minute half-life temperature does not decompose; and bonding the anisotropic conductive film to the connection portions by thermocompression bonding at a second temperature at which an organic peroxide having a higher one-minute half-life temperature decomposes.

12. A connection structure produced by connecting a connection portion of a first wiring substrate and a connection portion of a second wiring substrate through the anisotropic conductive film according to claim 1 by anisotropic conductive connection.
